(19) United States
(12) Patent Application Publication
(10) Pub. No.: US 2002/0182319 A1
(43) Pub. Date: Dec. 5, 2002

(54) Method for depositing a coating on the wall of metallic containers

(76) Inventors: Mohamed Ben-Malek, Saint Martin d'Heres (FR); Alain Jupin, Sainte Menehould (FR)

Correspondence Address: DENNISON, SCHULTZ & DOUGHERTY, 1745 JEFFERSON DAVIS HIGHWAY, ARLINGTON, VA, 22202, US

(21) Appl. No.: 10/148,180

(22) PCT Filed: Dec. 6, 2000
(86) PCT No.: PCT/FR00/03418

(30) Foreign Application Priority Data
Dec. 6, 1999 (FR) 99/15376

(51) Int. Cl. B05D 7/22; C23C 16/00

(52) U.S. Cl. 427/237; 427/239; 427/569; 427/255.28

(57) ABSTRACT

The invention relates to a method for depositing a coating on the wall of a metal container. According to said method, the coating is deposited using a plasma at a pressure close to atmospheric pressure. The metallic container can be an aerosol dispenser can and the resulting coating advantageously replaces the internal layer of varnish usually deposited in containers of this type.

### FIELD OF THE INVENTION

The invention relates to a method enabling the deposition of a coating protecting the inner or outer surface of metal containers. Said containers are intended to contain liquid to pasty products such as pharmaceutical, parapharmaceutical, cosmetic and nutritional products. They may consist of dispensers of products in aerosol, foam or gel form using a pressurised gas.

### STATE OF THE RELATED ART

Metal containers protect the products they contain from outside contamination or a degradation of their formulation by evaporation of one of their ingredients. The metal wall is an excellent diffusion barrier for gases and aromas. However, it is often preferable for this wall to be in direct contact with said products. Said contact may be maintained for several years under relatively high temperature conditions specified within the scope of the use of this type of packaging (approximately 50° C.) and such conditions make it impossible to prevent a certain susceptibility to corrosion, irrespective of the metal used. For this reason, the metal wall is generally coated on the inside with a layer of varnish intended to act as a durable barrier in the vicinity of 50° C. between the propellant, products and said metal wall.

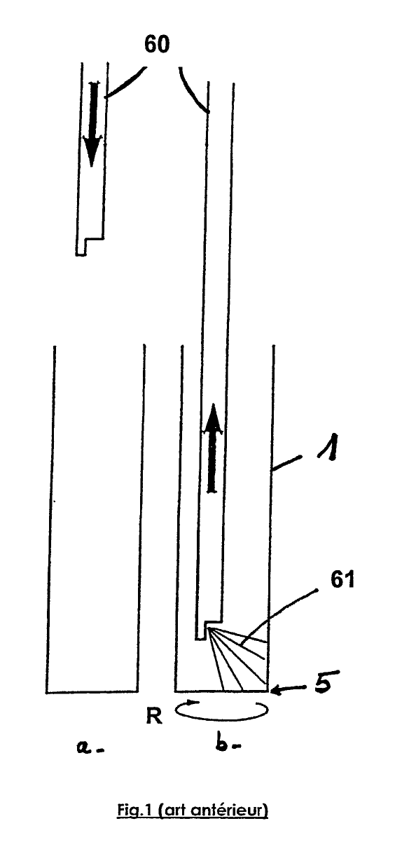

The type of varnish and its thickness are selected according to the products or the propellant contained. They generally consist of epoxy-phenol compounds, vinyl organosols, polyesters, imide polyamides, etc. The varnish is deposited on the inner wall of the container by a spray gun which enters the rotated container at a varying depth (see FIG. 1). The varnish is then dried by heat treatment or polymerised by UV excitation. However, irrespective of the type of varnish used, a low-ductility layer is obtained, generally decreasing in ductility as its diffusion barrier properties improve. Due to this low ductility, it is necessary to limit the plastic deformation subsequently applied to the container.

### PROBLEM STATEMENT

The problem relates to all types of metal containers wherein the diameter of the neck surrounding the dispensing orifice is less than the diameter (or a large characteristic dimension) of the body of the container. We will illustrate this problem with aerosol dispensers, which comprise a base, a roughly cylindrical body and shoulder-shaped neck joining the cylindrical body to an opening, of a diameter roughly less than that of the cylindrical body. Said opening is surrounded by a rolled edge, on which a tray supporting the dispensing valve is attached.

The application of the varnish on the inner surface is particularly delicate in the case of one-piece containers. In the case of containers produced with an added base and/or dome, it is possible to deposit varnish on the parts already deformed, the operation being performed before the assembly of each of said parts. However, said containers have inferior aesthetic qualities to those of one-piece containers and involve more risks of tightness loss. Aluminium alloys offer the advantage of allowing one-piece production: a blank with a base and cylindrical wall is shaped by impact extrusion (or drawing), possibly followed by drawing passes and the open end of the cylindrical blank is then coned (neck formation), trimmed and driven to form a rolled edge intended to receive the valve tray.

It is difficult to deposit varnish when the multi-piece container is already assembled or when the one-piece container is fully shaped. The accessibility of the spray gun inside the container is indeed restricted due to the small diameter of the neck opening (generally one inch or less) such that the thickness of the coating cannot be regular inside the container.

Indeed, in order to varnish inside the container when said container is fully shaped, it is necessary to have a base of a sufficiently even shape to enable the spray guns to diffuse the varnish over the entire wall of the base. The base is conventionally shaped like an outer toric base surrounding a concave dome intended to enhance the internal pressure resistance. To cover the entire wall of the base with varnish, it is necessary to have a toric base which is as wide and shallow as possible. In addition, even if the varnish is deposited before the open end is coned, it is necessary to use very thin nozzles which are delicate to use since they are fragile and become blocked easily and apply a relatively long path, to cover all the inner surface as regularly as possible, which limits production rates considerably.

Therefore, the varnish is generally deposited on the inner face of the container blank, i.e. before coning of the open end and before full shaping of the base. While the contraction corresponding to the coning is accepted relatively well by the varnish due to the compressive nature of the strain generated, the same does not apply for the driving operations intended to produce the rolled edge and for the container shaped operations, these two types of shaping involving traction strains and resulting relatively rapidly in the creation of cracking on the varnish. This results in a loss of the desired barrier properties.

In this way, to avoid the loss of these barrier properties, those skilled in the art are required either to choose a more ductile, but less effective varnish or to limit the subsequent deformation of the container blank to the strict minimum, which restricts the conditions for use of the aerosol containers produced (smaller diameter and therefore smaller capacity). Therefore, those skilled in the art are faced with a rarely satisfying compromise.

Methods are known in the prior art, enabling the coating of inner surfaces of metal containers such as beverage cans. In this way, WO95/22413, DE 43 18 086 and FR 2 776 540 disclose complex devices enabling, at very high throughputs, the deposition of a coating assisted by plasma on the inner surface of a container. The methods implemented are all characterised in that they apply a relatively high vacuum inside the container. To meet this dual constraint: very high throughputs and high vacuum, said devices are necessarily very costly and can only be redeemed economically with the production of a considerable quantity of containers processed in this way.

### PROBLEM STATEMENT

The applicant researched a reliable method to obtain a coating protecting the wall of metal containers effectively, said method having to be economically satisfactory for the manufacture of metal containers which, such as containers for aerosol dispensers, are produced at throughputs and in quantities typically ten to one hundred times lower than beverage cans.

### SUBJECT OF THE INVENTION

The invention relates to a method to deposit a coating on the surface of a metal container, said method being assisted by plasma, characterised in that said method is carried out at a pressure close to atmospheric pressure.

According to the invention, said deposition is carried out using a surface treatment plasma reactor. The plasma may be generated in different types of discharges: arc, luminescent discharge, discharge via a dielectric barrier or corona type discharge with different types of excitation: microwaves, radiofrequencies, medium frequency alternating current. The latter two types of plasma generation offer the advantage of being able to be carried out at a pressure close to atmospheric pressure.

When performing coating by condensation after decomposition of a gaseous substance or compound, the plasma may be generated either by dielectric barrier discharge or corona type discharge between the container and en electrode; in this case, the air gap must be relatively narrow, the deposition is preferentially carried out before coning;

or using a transferred plasma generation mode: the plasma is formed outside the treatment zone by means of an arc discharge or a microwave or radiofrequency discharge. Said plasma is then introduced inside the container by means of a coupling which is used to ensure the homogeneous distribution of the coating on the inner surface of said container. The container is thus in a post-discharge position.

With an operating pressure close to atmospheric pressure, the deposition treatment time is considerably reduced. Incorporated in the production line or performed outside the line (in batch mode), this treatment becomes economically compatible with production rates of the order of several hundred units per minute.

The coating may be treated in “batch mode” on a quantity of containers related to the continuous flow of containers from the production line. The batch treatment may be performed completely independently of the production line which includes lacquering and/or over-varnishing of the outer surface of the containers. However, it is also possible to envisage the incorporation of the treatment in the production cycle.

The material to be deposited may be any material not reacting with the products and propellant intended to be contained in the container. Preferentially, carbon with polymeric tendency, i.e. comprising a network of amorphous carbon chains with hydrogen bonds, silica, alumina, any oxide, nitride or carbide or their mixture or combination of one or more of the following metals (Si, Mg, Al, Ti, Zr, Nb, Ta, Mo, W, V) or a polymerised plastic under plasma assistance is selected.

Irrespective of the selected plasma generation the target deposition thickness is between 150 Å and 1500 Å, preferentially 200 to 500 Å. The target order of magnitude of the deposition rate is 100 Å/s. This is the order of 50 Å/s when cold plasma (corona or dielectric type discharge) is used; however, it may exceed 300 Å/s with thermal plasma type plasma. In this way, the deposition time may be limited to a few seconds, or even a few tenths of a second with thermal plasma type plasma. Even if it is necessary to treat several containers at the same time, it is possible to introduce into the production line accumulators of the same size as those used in the prior art to dry the varnish. The method allowing a higher deposition rate is preferred if it involves introducing an integrated treatment device into the production line.

For the deposition of carbon with polymeric tendency, a gas chosen from alkanes, alkenes or alkynes or their mixtures is preferentially chosen as the precursor gas.

For silica deposition, HMDSO (hexamethyl-disiloxane) or TMDSO (trimethyl-disiloxane) is preferentially used as the precursor gas. For alumina deposition, an organometallic compound, such as tributyl aluminium Al(C₄H₉)₃ or triethyl aluminium is preferentially used as the precursor gas, which is circulated diluted in an argon and oxygen mixture. By adjusting the proportion of oxygen, deposits containing a certain proportion of carbon of up to 20% are produced. The applicant observed on such deposits that higher ductility properties were obtained as the richness in carbon of the deposit increased, probably because the silica or alumina network, wherein the carbon is to be incorporated, is looser.

Similarly, when carbon deposition is carried out, it is preferable to mix the selected precursor (e.g. acetylene) with one of the gases mentioned above (HMDSO, TMDSO, tributyl aluminium) so as to obtain enhanced barrier properties. For depositions carried out on container blanks intended for subsequent deformation, the mixture is determined such that the aluminium or silicon content of the deposit is approximately or less than 5%. This consists of improving the adherence of the deposit on the substrate but not degrading the ductile properties of the deposit excessively and thus preventing peeling during the subsequent deformation.

Said method offers the advantage of being possible at a pressure close to atmospheric pressure, preferentially between 200 and 760 millimeters of mercury. A slightly lower pressure than atmospheric pressure enables better control of the purity of the gas circulating in the container. Prior flushing is preferentially carried out with an inert gas, such as argon to prevent the formation of impurities (risk of reaction with nitrogen in air, water vapour, etc.) liable to deteriorate the quality of the adherence of the layer deposited.

In a first alternative embodiment of the invention, the deposition is carried out in line by dielectric discharge, preferentially in the middle of the production line on container blanks not yet coned. An electrode of a suitable shape is introduced into the base and the cylindrical wall of the blank. To obtain regular deposition, the electrode must be as close as possible to the wall to be coated (distance typically less than one centimeter). This suggests the use of an electrode fitting the inside of the container, which can be introduced into the container before coning. The electrode is introduced into the inner volume of the container. The electrode, descending relatively low in the container is preferentially hollow, so as to supply the inside of the container with precursor gas. It is coated with a polypropylene type plastic over a thickness at least equal to 20 μ. The electrode must be replaced (at least recoated) regularly since the polymer decomposes during the treatment. However, the carbon released may be used for the formation of the carbon with polymeric tendency of the coating to be deposited, making it possible to reduce the quantity of precursor gas consumed.

For this first alternative embodiment, it is preferable to limit the deposition thickness to 300 Å. A coating comprising carbon with polymeric tendency obtained by decomposition of a precursor comprising an alkene type gas is preferentially chosen. It is also possible to deposit a low cross-linking varnish obtained by plasma polymerisation.

The coating obtained, considerably thinner than the layer of varnish according to the prior art and adhering better on its substrate, tolerates the subsequent compressive deformation applied by the coning without cracking and thus losing the effectiveness of its barrier properties.

In order to obtain a good adherence of the deposited layer, it is preferable for the substrate to have, just before the deposition treatment, an activated, or at least well cleaned substrate.

This surface preparation may be carried out by means of the treatment provided in the prior art, or, before inner varnishing, the traces of lubricant (zinc stearate or equivalent) used are removed to facilitate the impact extrusion by performing preferentially thermal degreasing, or chemical degreasing such as one of those conventionally used, i.e. using a perchloroethylene type diluent or performing hot scrubbing inside the container with caustic soda followed by bleaching with nitric acid.

The containers are removed from the transfer line in the same way as that used for the inner varnish deposition. Since the cycle should be 5 to 15 times longer than that for varnishing, it is preferable to place the containers on one or more turntables larger in diameter than that of the turret used for varnish deposition. The containers are held by a device similar to that used on the coning machines. Preferentially, the bases are set to the final shape (toric base surrounding a concave dome) for example by driving before the shaped electrode is introduced into the container.

In a second alternative embodiment of the invention, the deposition is carried out with a transferred plasma generation mode, either outside the line, or preferentially in line, at the end of the production line when the container is coned and the rolled edge is produced around the opening. The second example shows a device where the plasma is formed by high-frequency arc excitation. The plasma is introduced inside the container via a perforated, insulating and heat-resistant coupling. Said coupling is introduced inside the container and its open end is placed in the vicinity of the base such that the plasma has to circulate from the base of the container to the opening. It is perforated along its entire length to allow plasma to circulate throughout the inner volume of the container. When extremely high deposition rates are desired, it is planned to cool said coupling by means of a double wall system with water circulation between the walls.

In a third alternative embodiment of the invention, the deposition is carried out in line by corona discharge, preferentially at the end of the production line, on containers already coned. An electrode of a suitable shape is introduced into its opening: its orthogonal section has a contour comprising a large number of convexities and acute angles oriented outwards; but its outer contour has a diameter less than that of the opening. As such, the metal electrode may be introduced easily into the already coned container and comprises longitudinal convexities and edges oriented towards the inner wall of the container. Such an electrode geometry favours the peak effect favourable for this type of discharge. As in the other alternative embodiments, the electrode, descending relatively low into the container, is preferentially hollow, so as to supply the inside of the container with precursor gas.

Naturally, there is no reason why a deposition cannot also be performed on the outside of the container wall. In addition, even though the production of a metal container for a dispenser of products in the form of aerosols has been described to illustrate the invention, it also applies to the production of any metal container for which the wall is to be isolated from the product that it is intended to contain.

FIG. 1 illustrates the spray gun used for the coating of a varnish used in the prior art. The spray gun 60 is introduced into the container blank 1 (FIG 1b), i.e. the container obtained after extrusion but before coning and shaping of the base 5. The blank is rotated R and the spray gun 60 distributes the varnish 61 on the inner face of said blank.

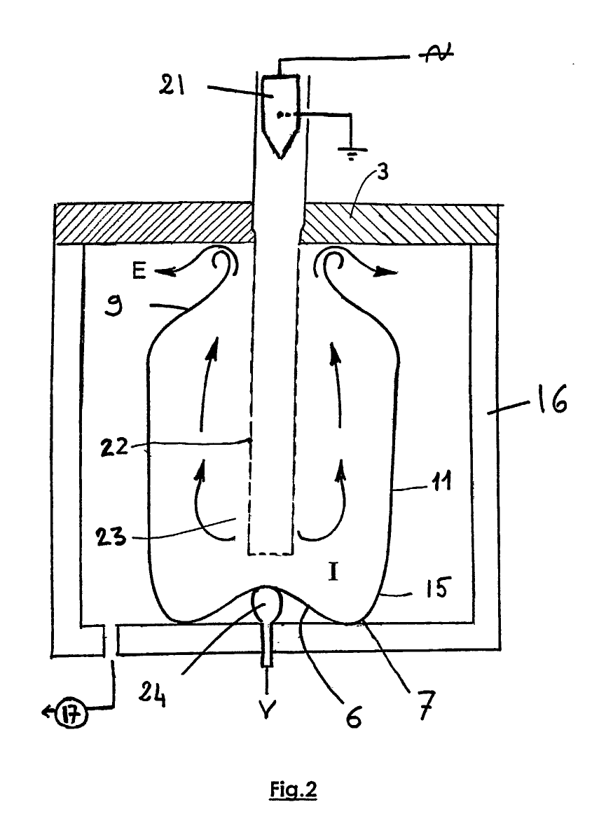

FIG. 2 represents a device used to coat the inside of containers by plasma excitation at a pressure close to atmospheric pressure according to the second alternative embodiment of the invention.

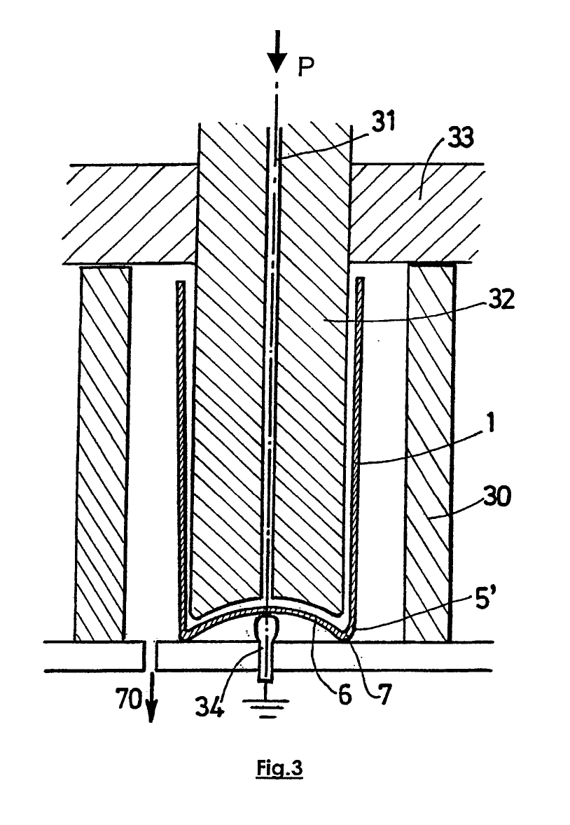

FIG. 3 is a schematic representation of a device used to coat the inside of containers by plasma excitation at a pressure close to atmospheric pressure according to the first alternative embodiment of the invention.

### EMBODIMENTS OF THE INVENTION

### EXAMPLE 1

### Deposition of an Alumina Coating on the Inner Wall of a One-piece Aerosol Container (FIG. 2)

This example corresponds to the second alternative embodiment of the invention: the method used makes it possible to coat the inner surface of a container 11 already shaped, comprising a neck 9 and a base 15, composed of a toric base 7 surrounding a concave dome 6.

The container 11 is placed in a confinement 16 wherein it is possible to produce a negative pressure of the order of 300 mm of mercury very rapidly. A small electrode 24 located in the centre of the confinement is brought into contact with the base 15 and a potential V is applied to the container to control the quality and regularity of the deposition obtained.

The assembly is moved such that it is placed opposite a transferred plasma generation device 21 attached to a coupling 22. The coupling 22 is then introduced into the container 11. Before the plasma is formed, the pressure is increased to 300 mm of mercury and argon is injected via the coupling 22 such that the stagnant ambient air in the container is evacuated outside the confinement.

The coupling 22 is generally made of quartz or ceramics. In this case, an alumina-zirconium mixture is used. It comprises a large number of perforations 23 of a small diameter (<0.1 mm) through its thickness (of the order of 3 mm). Said perforations are produced all along the coupling 22. Before and during the generation of the plasma, the pumping means 17 of the confinement 16 operate and create a pressure differential between the inside I of the container and the confinement E such that the gas injected into the container circulates upwards towards the neck.

A tributyl aluminium (10%), argon (85%) and oxygen (5%) mixture is used as the precursor gas. The plasma, generated by an excited source at 250 kHz at a voltage of 10 kV, touches the inner surface of the container, providing the constituents composing the coating which is essentially composed of alumina but comprises some carbon with polymeric tendency. Around ten seconds is sufficient to obtain a 250 Å coating.

### EXAMPLE 2

### Deposition of a Mixed Carbon with Polymeric Tendency and Silica Coating on the Inner Wall of an Aerosol Container Blank (FIG. 3)

This example illustrates the first alternative embodiment of the invention. It consists of the deposition of a coating on the inner surface of containers in the middle of the production line, i.e. at a stage when the container is not yet coned. This stage is located in the production line exactly at the current varnish deposition stage of the prior art, which this method proposes to replace.

The electrode 32 has a shape fitting to within 2 mm the shape of the inner surface of a drawn extruded container blank 1. It is coated with a 20 μ layer of polypropylene. The base of the blank has already been shaped: it comprises a toric base 7 surrounding a concave dome 6. The electrode is pierced with a duct 31 used to supply the precursor gas P in the air gap between the electrode and the container.

The container is placed inside a coupling 30. A cap 33 comprising the electrode 32 is placed over the assembly, inside which primary pumping means are actuated before the fitting of the cap, such that the air is expelled 70 from inside the coupling and the container and is replaced by the inert gas conveyed from inside the electrode. A pressure close to 300 mm of mercury is reached inside the confinement. In the base of the coupling, a contactor 34 is pressed against the base 5′ of the container. Said container is grounded and around twenty kV are applied on the electrode. The gas, an acetylene-HMDSO-argon mixture, wherein the flow rate corresponds to 20 sccm, 10 sccm and 15 sccm (where sccm is a unit signifying standard cubic cm per minute) respectively is injected and the plasma is generated by an excited source at a frequency of 250 kHz. A few seconds are sufficient to obtain a regular deposit of the order of 250 Å.

It is possible not to use a confinement and perform the treatment at atmospheric pressure; in this case, it is preferable to flush argon prior to the plasma treatment so as to evacuate the stagnant air. Therefore, the deposition in this case requires a few more seconds.

### EXAMPLE 3

### Deposition of an Alumina Coating on the Inner Wall of an Aerosol Container Blank

This example corresponds to the third alternative embodiment of the invention, where the deposition is carried out by corona discharge at the end of the production line, on already coned containers.

An electrode of a suitable shape is introduced into the opening: its orthogonal section has a contour comprising a large number of convexities and acute angles oriented outwards, but its outer contour has a diameter less than that of the opening (25.4 mm). As such, the metal electrode may be introduced easily into the already coned container (diameter of cylindrical body of container: 45 mm) and comprises longitudinal convexities and edges oriented towards the inner wall of the container.

The electrode is hollow, which makes it possible to supply the inside of the container with precursor gas. A tributyl aluminium (10%) argon (85%) and oxygen (5%) mixture is injected as the precursor gas.

The container is the anode, the electrode the cathode. A pulsating voltage of 15 kV at 200 kHz is applied. The plasma is generated between the edges of the electrode and the inner wall of the container at a distance of around ten mm from said edges and touches the inner surface of the container providing the constituents composing the coating which is essentially composed of alumina but comprises some carbon with polymeric tendency.

An isolating coupling is placed at the top of the electrode, making it possible to prevent a preferential deposit on the neck.

### Advantages of the Method According to the Invention

Advantages relating more specifically to the manufacture of containers for aerosol dispensers:

the deposit is thin and deformable: the barrier properties are maintained;

the deposit is regular;

possibility to define less even base shapes, particularly with a narrower toric base;

it is no longer necessary to equip the production line with heat treatment chambers to dry varnish.

1. Method to deposit a coating on the surface of a metal container, said wherein the coating deposited using a plasma, characterised in that the plasma is generated at a pressure close to atmospheric pressure.

2. Method according to claim 1 where the plasma is generated at a pressure between 200 and 760 millimeters of mercury.

3. Method according to claim 1 or 2, where the deposition is preceded by flushing with an inert gas.

4. Method according to any of claims 1 to 3 where said coating has thickness between 150 and 1500 Å and comprises a material or a mixture of materials belonging to the following group: carbon with polymeric tendency, oxides, nitrides or carbides or their mixture or combination of one or more of the following metals (Si, Mg, Al, Ti, Zr, Nb, Ta, Mo, W, V).

5. Method according to any of claims 1 to 4 where said metal container is an aerosol dispenser and where its inner surface is coated before coning.
